(19) United States
(12) Patent Application Publication
(10) Pub. No.: US 2016/0062161 A1
(43) Pub. Date: Mar. 3, 2016

(54) LIQUID CRYSTAL DISPLAY AND MANUFACTURING METHOD THEREOF

(71) Applicant: SAMSUNG DISPLAY CO., LTD., Yongin-City (KR)

(72) Inventors: Sun Hwa LEE, Hwaseong-si (KR); Kwang-Chul JUNG, Seongnam-si (KR); Mee Hye JUNG, Suwon-si (KR)

(21) Appl. No.: 14/631,997

(22) Filed: Feb. 26, 2015

(30) Foreign Application Priority Data
Sep. 2, 2014 (KR) 10-2014-0116436

(51) Int. Cl. G02F 1/1368; G02F 1/1345; G02F 1/1335; H01L 27/12; G02F 1/1362; G02F 1/1333

(52) U.S. Cl. CPC G02F 1/1368; G02F 1/136286; G02F 1/133377; G02F 1/133514; G02F 1/136204; H01L 27/124; H01L 27/1262; G02F 1/13458

(57) ABSTRACT

A liquid crystal display includes a mother substrate with a plurality of unit substrate regions, a first voltage supplying wire and a second voltage supplying wire, each of the first and second voltage supplying wires being between neighboring unit substrate regions, a first cell pad and a second cell pad on each unit substrate region, a first connection bridge connecting the first voltage supplying wire, the first cell pad, and the second cell pad, and a second connection bridge connecting the second voltage supplying wire, the first cell pad, and the second cell pad, wherein each of the unit substrate regions includes a thin film transistor, a pixel electrode connected to the thin film transistor, liquid crystal in a microcavity on the pixel electrode, a common electrode on the liquid crystal, and an overcoat covering the liquid crystal and the common electrode.

### CROSS-REFERENCE TO RELATED APPLICATION

Korean Patent Application No. 10-2014-0116436, filed on Sep. 2, 2014, in the Korean Intellectual Property Office, and entitled: “Liquid Crystal Display and Manufacturing Method Thereof,” is incorporated by reference herein in its entirety.

### BACKGROUND

1. Field

Embodiments relate to a liquid crystal display and a manufacturing method thereof.

2. Description of the Related Art

A liquid crystal display is a flat panel display. The liquid crystal display is configured with two display panels on which electric field generating electrodes, such as a pixel electrode and a common electrode, are formed, and a liquid crystal layer provided therebetween. A voltage is supplied to the electric field generating electrodes to generate an electric field to the liquid crystal layer, alignment of liquid crystal molecules of the liquid crystal layer is determined, and polarization of incident light is controlled, thereby displaying images.

In general, the liquid crystal display is classified as a twisted nematic type, a horizontal electric field type, and a vertical alignment type depending on characteristics of the liquid crystal layer. A patterned vertically aligned (PVA) mode belongs to the vertical alignment type, and has been developed to realize a wide viewing angle.

In order to increase a response speed of the liquid crystal molecules, an electric field exposure process for the liquid crystal molecules to have a pretilt while no electric field is applied has been developed. For example, the liquid crystal molecules can be controlled to have a pretilt in a specific direction by applying an electric field to the liquid crystal layer to which a prepolymer material that is polymerized by heat or rays such as ultraviolet rays or by irradiating heat or beams of light to the liquid crystal layer.

In general, to improve productivity, the substrate is not manufactured for a single product, e.g., a single screen of a mobile phone, but for a mother substrate including a plurality of substrates for products. A voltage is applied to the pixel electrode provided on the lower substrate and to the common electrode provided on the upper substrate to apply an electric field to the liquid crystal layer on the plurality of substrates. Beams of light are irradiated to form a light hardened layer, while the electric field is applied to the liquid crystal layer, to thus progress an electric field exposure process.

### SUMMARY

Embodiments provide a liquid crystal display for performing an electric field exposure process to a mother substrate including a plurality of unit substrate regions, and a manufacturing method thereof.

An exemplary provides a liquid crystal display including a mother substrate with a plurality of unit substrate regions, a first voltage supplying wire and a second voltage supplying wire, each of the first and second voltage supplying wires being between neighboring unit substrate regions, a first cell pad and a second cell pad on each unit substrate region, a first connection bridge connecting the first voltage supplying wire, the first cell pad, and the second cell pad, and a second connection bridge connecting the second voltage supplying wire, the first cell pad, and the second cell pad, wherein each of the unit substrate regions includes a thin film transistor, a pixel electrode connected to the thin film transistor, liquid crystal in a microcavity on the pixel electrode, a common electrode on the liquid crystal, and an overcoat covering the liquid crystal and the common electrode.

The liquid crystal display may further include a lower alignment layer provided on the pixel electrode, and an upper alignment layer display provided on the microcavity layer.

The liquid crystal display may further include a color filter formed on the common electrode.

The liquid crystal display may further include a first voltage supplying pad formed on one end of the first voltage supplying wire and a second voltage supplying pad formed on one end of the second voltage supplying wire.

The first voltage supplying wire and the second voltage supplying wire may be formed with a same material as a gate line or a data line provided in the unit substrate regions.

The liquid crystal display may include a guard ring for surrounding the unit substrate regions, provided between the first voltage supplying wire, the second voltage supplying wire, the first cell pad, and the second cell pad, and preventing static electricity from being input to the unit substrate regions.

The first cell pad may be connected to a gate line formed in the unit substrate regions, and the second cell pad may be connected to a data line formed in the unit substrate regions.

The first cell pad and the second cell pad may be formed of a same material as a gate line or a data line formed in the unit substrate regions.

The guard ring is formed of a material of at least one of a gate line, a data line, or a pixel electrode formed in the unit substrate regions.

The guard ring may be divided into an overlapped area through which the first connection bridge and the second connection bridge pass, and a non-overlapped area through which the first connection bridge and the second connection bridge do not pass.

The overlapped area on the guard ring may include a light blocking layer, and the non-overlapped area on the guard ring includes a sacrificial layer.

The light blocking layer may be formed of a same material as a light blocking member formed in the unit substrate regions.

The sacrificial layer may be formed of a photoresist for forming the microcavity layer.

The first connection bridge and the second connection bridge may be formed of a same material as the common electrode.

Another embodiment provides a method for manufacturing a liquid crystal display, including providing a mother substrate including a plurality of unit substrate regions; forming a thin film transistor provided in the unit substrate regions, a pixel electrode connected to the thin film transistor, liquid crystal provided in a microcavity on the pixel electrode, a common electrode provided on the liquid crystal, and an overcoat for supporting the microcavity and covering the liquid crystal and the common electrode; forming a first voltage supplying wire and a second voltage supplying wire between the neighboring unit substrate regions; forming a first cell pad and a second cell pad provided between the first voltage supplying wire, the second voltage supplying wire, and the unit substrate regions, a first connection bridge for connecting the first voltage supplying wire, the first cell pad, and the second cell pad, and a second connection bridge for connecting the second voltage supplying wire, the first cell pad, and the second cell pad; pre-tilting the liquid crystal by supplying a voltage to the pixel electrode and the common electrode; and hardening the alignment aid by irradiating beams to the mother substrate.

The method may further include forming a first voltage supplying pad at one end of the first voltage supplying wire and a second voltage supplying pad at one end of the second voltage supplying wire.

The first cell pad may be connected to a gate line formed in the unit substrate regions, and the second cell pad is connected to a data line formed in the unit substrate regions.

The hardening of the alignment aid by irradiating beams to the mother substrate may include irradiating ultraviolet rays from a lower portion of the mother substrate.

A guard ring for surrounding the unit substrate regions, may be provided between the first voltage supplying wire, the second voltage supplying wire, the first cell pad, and the second cell pad, and preventing static electricity from being input to the unit substrate regions is further included.

The guard ring may be formed of a material of at least one of a gate line, a data line, or a pixel electrode formed in the unit substrate regions.

### BRIEF DESCRIPTION OF THE DRAWINGS

Features will become apparent to those of ordinary skill in the art by describing in detail exemplary embodiments with reference to the attached drawings, in which:

FIG. 1 illustrates a layout view of a mother substrate of a liquid crystal display according to an exemplary embodiment.

FIG. 2 illustrates an enlarged top view of a portion ‘A’ of FIG. 1.

FIG. 3 illustrates a cross-sectional view along line of FIG. 2.

FIG. 4 illustrates a cross-sectional view along line IV-IV of FIG. 2.

FIG. 5 illustrates a cross-sectional view along line V-V of FIG. 2.

FIG. 6 illustrates a layout view of a pixel of a mother substrate of a liquid crystal display according to an exemplary embodiment.

FIG. 7 illustrates a top plan view of a pixel of a mother substrate of a liquid crystal display according to an exemplary embodiment.

FIG. 8 illustrates a cross-sectional view of a pixel of a mother substrate of a liquid crystal display according to an exemplary embodiment.

FIG. 9 illustrates a perspective view of a microcavity layer according to an exemplary embodiment of FIG. 8.

FIG. 10 illustrates a flowchart of a method for manufacturing a liquid crystal display manufactured according to FIG. 1 to FIG. 9.

FIG. 11 illustrates a cross-sectional view along line IX-IX of FIG. 1.

FIG. 12A and FIG. 12B illustrate cross-sectional views of a process for a liquid crystal display to align liquid crystal according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

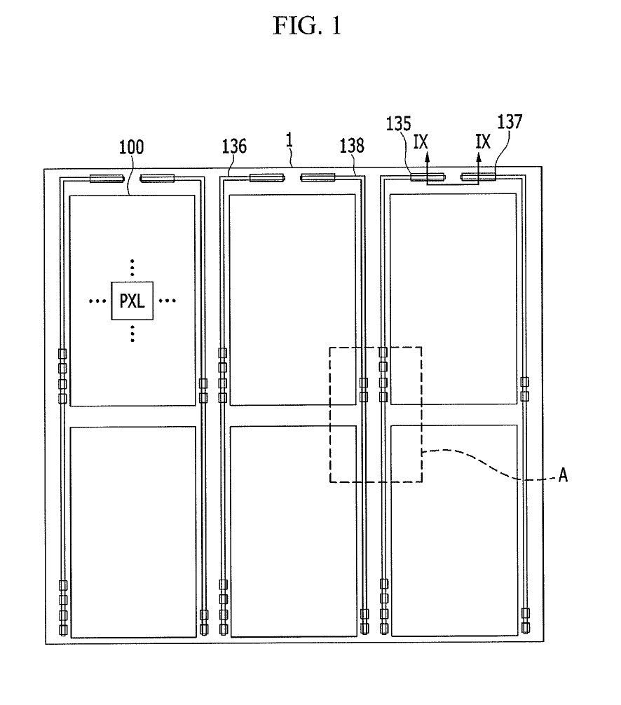

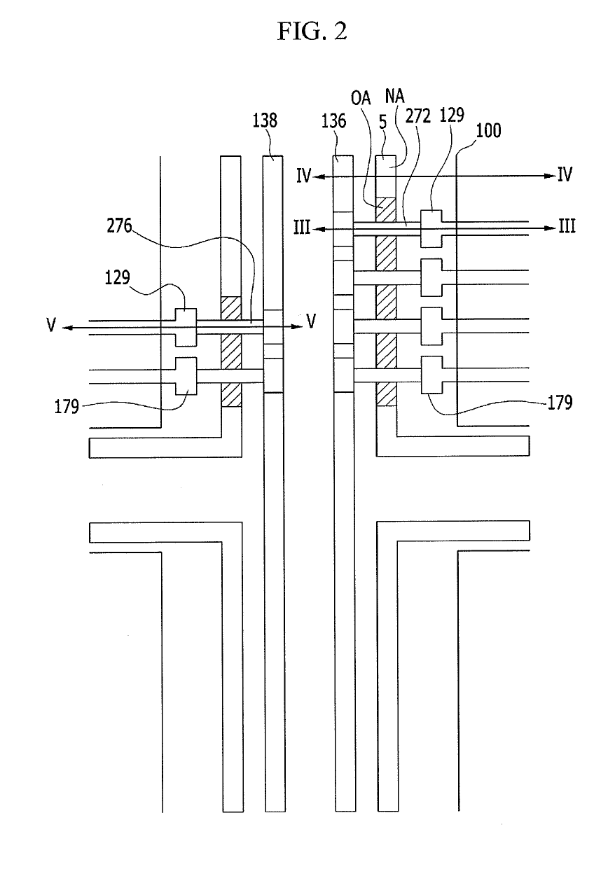

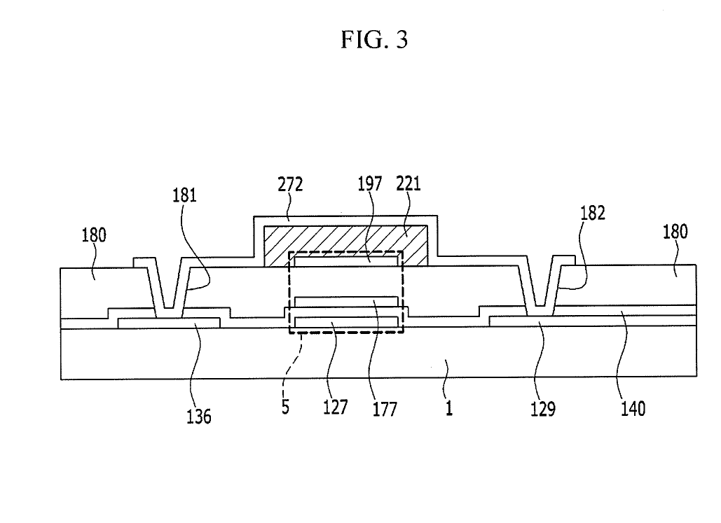

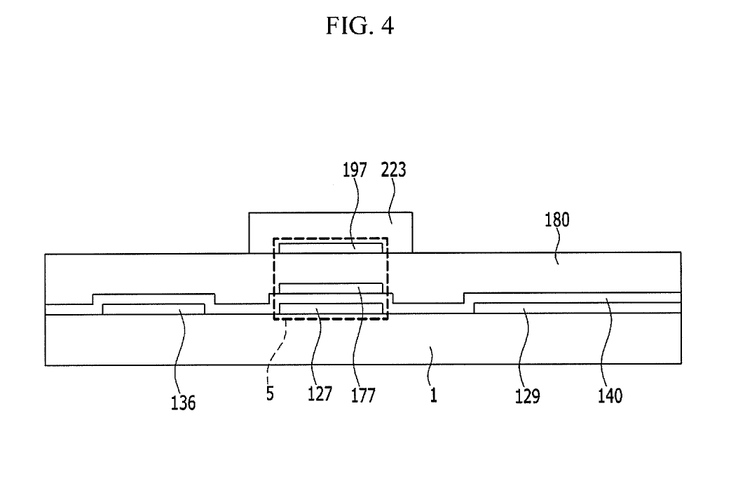

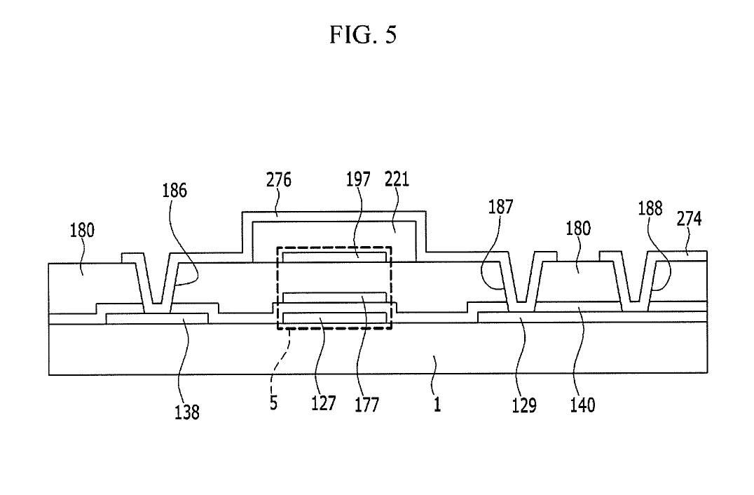

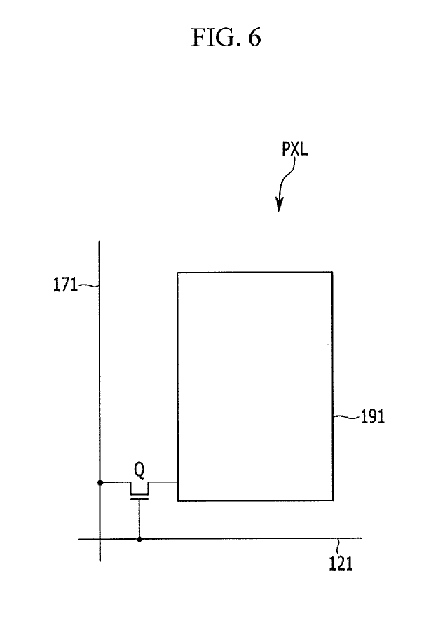

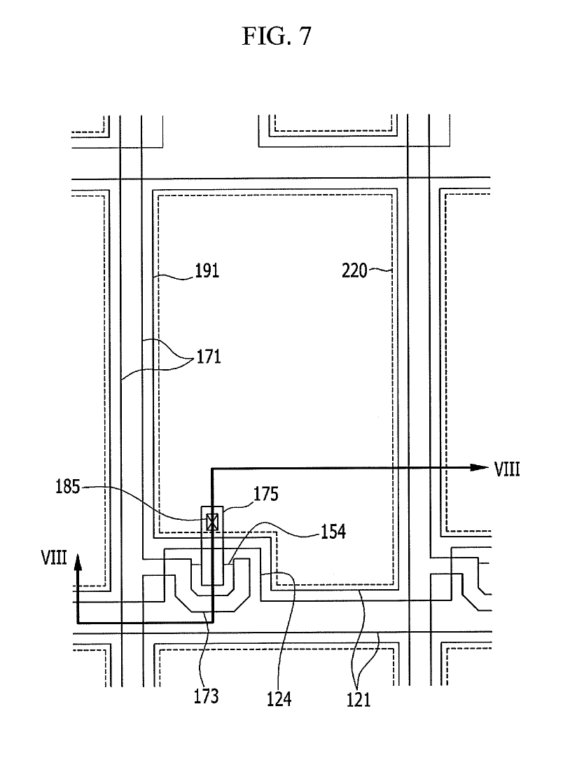

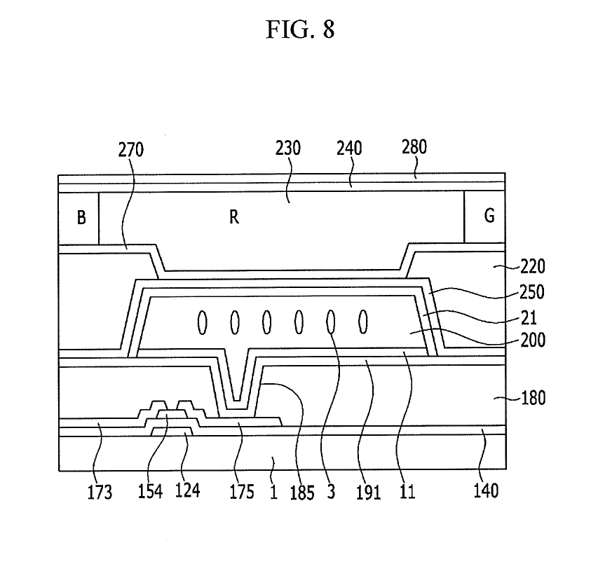

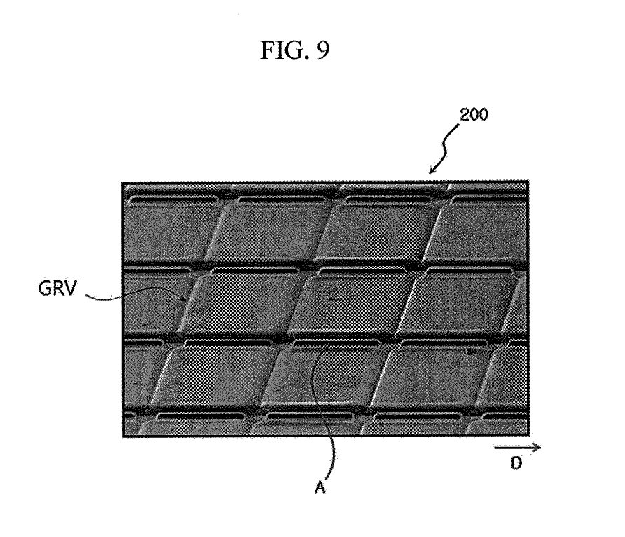

FIG. 1 shows a layout view of a mother substrate of a liquid crystal display according to an exemplary embodiment, FIG. 2 shows a top plan view of a portion ‘A’ of FIG. 1, FIG. 3 shows a cross-sectional view of a mother substrate of FIG. 2 with respect to a line FIG. 4 shows a cross-sectional view of a mother substrate of FIG. 2 with respect to a line IV-IV, FIG. 5 shows a cross-sectional view of a mother substrate of FIG. 2 with respect to a line V-V, FIG. 6 shows a layout view of a pixel of a mother substrate of a liquid crystal display according to an exemplary embodiment, FIG. 7 shows a top plan view of a pixel of a mother substrate of a liquid crystal display according to an exemplary embodiment, FIG. 8 shows a cross-sectional view of a pixel of a mother substrate of a liquid crystal display according to an exemplary embodiment, and FIG. 9 shows a perspective view of a microcavity layer according to an exemplary embodiment of FIG. 8.

Referring to FIG. 1 to FIG. 4, a plurality of unit substrate regions 100 arranged in a matrix form are formed on a mother substrate 1. Each unit substrate region 100 may include a plurality of signal lines and a plurality of pixel areas (PXL) connected thereto and substantially arranged in a matrix form from the viewpoint of an equivalent circuit. The signal lines include a plurality of gate lines for transmitting a gate signal (also called a scanning signal) and a plurality of data lines for transmitting a data voltage.

Referring to FIG. 6, regarding the liquid crystal display according to an exemplary embodiment, a pixel area (PXL) included in the mother substrate 1 may include at least one switching element Q connected to at least one data line 171 and at least one gate line 121, at least one pixel electrode 191 connected thereto, and a common electrode 270 facing the pixel electrode 191. The switching element Q includes at least one thin film transistor, and is controlled by the gate signal transmitted by the gate line 121 to transmit the data voltage provided by the data line 171 to the pixel electrode 191.

An example of a stacked configuration of a pixel area (PXL) included in a liquid crystal display according to an exemplary embodiment will now be described with reference to FIG. 6 to FIG. 9.

Referring to FIG. 6 to FIG. 9, a gate conductor, e.g., the gate line 121 including a gate electrode 124, is provided on the mother substrate 1. The mother substrate 1 may be formed, e.g., of transparent glass or plastic.

The gate line 121 transmits a gate signal and is generally extended in a horizontal direction. Each gate line 121 includes a plurality of gate electrodes 124 protruding from the gate line 121.

A gate insulating layer 140 is provided on the gate conductor, and a semiconductor 154, e.g., made of amorphous silicon, crystalline silicon, or an oxide semiconductor material, is provided on the gate insulating layer 140. An ohmic contact (not shown) is provided on the semiconductor 154, but it can be omitted.

The data line 171 including a source electrode 173 and a data conductor including a drain electrode 175 are provided on the semiconductor 154. The data line 171 transmits a data signal and is generally extended in a vertical direction to cross the gate line 121. Each data line 171 is extended toward the gate electrode 124 and is connected to a plurality of U-shaped source electrodes 173.

The drain electrode 175 is separated from the data line 171 and is extended toward an upper portion from a center of the U-shaped source electrode 173. The shape of the source electrode 173 and the drain electrode 175 is exemplar and is variable in many ways.

The gate conductor and the data conductor can be made of a conductive material, e.g., an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), titanium (Ti), and the like.

The gate electrode 124, the source electrode 173, the drain electrode 175, and the semiconductor 154 form a thin film transistor Q, and a channel of the thin film transistor is formed on the semiconductor 154 between the source electrode 173 and the drain electrode 175.

A passivation layer 180 made of an inorganic insulator or an organic insulator is provided on the data conductor. The passivation layer 180 includes a contact hole 185 for exposing the drain electrode 175.

The pixel electrode 191 is provided on the passivation layer 180. The pixel electrode 191 is physically and electrically connected to the drain electrode 175 through the contact hole 185 penetrating through the passivation layer 180, and receives the data voltage from the drain electrode 175. The pixel electrode 191 is made of a transparent conductor, e.g., ITO or IZO. Although not shown, the pixel electrode 191 can be formed with a plurality of small electrodes or fine slit electrodes.

A lower alignment layer 11 is formed on the pixel electrode 191. The lower alignment layer 11 is a vertical alignment layer or a horizontal alignment layer. The lower alignment layer 11 includes an alignment aid for initially aligning liquid crystal. The alignment aid is a reactive monomer, and can exemplarily include an ultraviolet ray hardening monomer. The lower alignment layer 11 can further include an ultraviolet ray hardening initiator. For example, the ultraviolet ray hardening monomer is an acrylate-based monomer, while the ultraviolet ray hardening initiator is made of a material absorbable in the ultraviolet ray region, e.g., 2,2-dimethoxy-1,2-diphenyl ethanone.

A microcavity layer 200 is provided on the lower alignment layer 11. A liquid crystal material including liquid crystal molecules 3 is injected into the microcavity layer 200, and the microcavity layer 200 includes a liquid crystal injection hole (A). The microcavity layer 200 is formed in a column direction of the pixel electrode 191. In the present exemplary embodiment, the liquid crystal material is injected into the microcavity layer 200 by using capillary force.

Referring to FIG. 9, the microcavity layer 200 includes a plurality of regions divided by a plurality of grooves (GRV) provided in a portion overlapping the gate line 121. The grooves (GRV) are formed in a direction in which the gate line 121 is extended. The plurality of regions of the microcavity layer 200 correspond to respective pixel areas and are provided in a direction (D) in which the gate line 121 is extended.

The liquid crystal injection hole (A) is provided between the lower alignment layer 11 and an upper alignment layer 21, and is formed in a direction in which the groove (GRV) is extended.

The groove (GRV) has been described to be formed in the direction in which the gate line 121 is extended in the present exemplary embodiment, but the groove (GRV) can be formed in a direction in which the data line 171 is extended in another exemplary embodiment. In this case, the plurality of regions of the microcavity layer 200 are provided in a vertical direction, and the liquid crystal injection hole (A) is formed in the direction in which the data line 171 is extended.

The upper alignment layer 21 is provided on the microcavity layer 200. The upper alignment layer 21 can be a vertical alignment layer or a horizontal alignment layer. The upper alignment layer 21 includes an alignment aid for initially aligning liquid crystal. The alignment aid is a reactive monomer, and for example, it includes an ultraviolet ray hardening monomer. The lower alignment layer 21 further includes an ultraviolet ray hardening initiator. For example, the ultraviolet ray hardening monomer is an acrylate-based monomer, and the ultraviolet ray hardening initiator is formed with a material that can be absorbed into the ultraviolet ray region, e.g., 2,2-dimethoxy-1,2-diphenyl ethanone.

An overcoat 250 is provided on the upper alignment layer 21. The overcoat 250 is formed, e.g., with a silicon nitride (SiNₓ) or a silicon oxide (SiOₓ). A light blocking member 220 is formed on the overcoat 250 in a direction in which the gate line 121 and the data line 171 are extended. The light blocking member 220 includes the groove (GRV) provided on a portion overlapping the gate line 121. The light blocking member 220 is provided on a portion substantially excluding a pixel area (not shown). The light blocking member 220 is also called a black matrix and prevents light leakage.

The common electrode 270 is provided on the light blocking member 220 and the overcoat 250. The common electrode 270 receives the common voltage, generates an electric field together with the pixel electrode 191, to which the data voltage is applied, and determines a direction in which the liquid crystal molecules 3 provided on the microcavity layer 200 between the electrodes are inclined. The common electrode 270 forms a capacitor (referred to as a liquid crystal capacitor) together with the pixel electrode 191, and maintains the supplied voltage after the thin film transistor is turned off.

A color filter 230 is provided on the common electrode 270. The color filter 230 is extended along a column of the pixel electrode 191. Each color filter 230 expresses one of primary colors such as red, green, and blue. However, without being restricted to the three primary colors of red, green, and blue, it can express one of cyan, magenta, yellow, and white-based colors.

An insulating layer 240 is provided on the color filter 230. The insulating layer 240 flattens and protects the color filter 230. The insulating layer 240 is formed of the same material as the overcoat 250, and is formed to cover a side of the light blocking member 220. However, the insulating layer 240 is not always needed and can be omitted.

A capping layer 280 is provided on the insulating layer 240. The capping layer 280 covers a liquid crystal injection hole (A) of the microcavity layer 200 exposed by the groove (GRV). The liquid crystal material is injected through the liquid crystal injection hole (A) of the microcavity layer 200 so the liquid crystal display is formed without forming an additional upper substrate.

Referring to FIG. 1 to FIG. 3, a plurality of first voltage supplying wires 136, a plurality of second voltage supplying wires 138, at least one first voltage supplying pad 135, a second voltage supplying pad 137, at least one first cell pad 129, and a second cell pad 179 are formed on the mother substrate 1.

The first voltage supplying wires 136 and the second voltage supplying wires 138 are provided between a plurality of neighboring unit substrate regions 100, and are extended along a column of the unit substrate region 100. For example, as illustrated in FIG. 1, the first voltage supplying wires 136 may be between two neighboring, i.e., adjacent, unit substrate regions 100 along a horizontal direction, and may, e.g., continuously, extend along a plurality of unit substrate regions 100 in a column, e.g., vertical, direction. In FIG. 1, the first voltage supplying wire 136 is exemplarily provided on the left of the unit substrate region 100, and the second voltage supplying wire 138 is exemplarily provided on the right of the unit substrate region 100. However, without being restricted to this, each of the first voltage supplying wire 136 and the second voltage supplying wire 138 can be provided on the left or the right of the unit substrate region 100.

Respective ends of a plurality of first voltage supplying wires 136 and second voltage supplying wires 138 are provided near respective facing edge sides of the mother substrate 1. The first voltage supplying pad 135 for receiving a voltage from an external device is formed on one end of the first voltage supplying wire 136, and the second voltage supplying pad 137 for receiving a voltage from an external device is formed on one end of the second voltage supplying wire 138.

The first voltage supplying wires 136 and the second voltage supplying wires 138 are formed of the same material as the signal lines, e.g., same material as the gate line 121 and the data line 171 provided on the unit substrate region 100, and are formed according to the same process as the signal lines or a different process therefrom.

The first cell pad 129 and the second cell pad 179 are provided among the first voltage supplying wires 136, the second voltage supplying wires 138, and the unit substrate region 100.

The first cell pad 129 and the second cell pad 179 are arranged in series along an edge side of the unit substrate region 100 substantially extending in the column direction. That is, the first cell pad 129 and the second cell pad 179 are arranged substantially in parallel with the first voltage supplying wires 136 and the second voltage supplying wires 138.

The first cell pad 129 and the second cell pad 179 are connected to the signal line formed in the unit substrate region 100. In detail, the first cell pad 129 is connected to the gate line 121 formed in the unit substrate region 100, and the second cell pad 179 is connected to the data line 171 formed in the unit substrate 100.

The first cell pad 129 and the second cell pad 179 are formed of the same material as the signal lines such as the gate line 121 and the data line 171 formed in a plurality of unit substrate regions 100, and are formed by the same process as the signal lines or a different process therefrom. However, without being restricted to this, the first cell pad 129 and the second cell pad 179 can be provided on a layer that is different from that of the signal lines such as the gate line 121 or the data line 171. The first cell pad 129 and the second cell pad 179 are provided in the unit substrate region 100.

The first voltage supplying wires 136 are connected to the first cell pad 129 and the second cell pad 179 through a plurality of first connection bridges 272, and the second voltage supplying wires 138 are connected to the first cell pad 129 and the second cell pad 179 through a plurality of second connection bridges 276.

A guard ring 5 for preventing inflow of static electricity to a plurality of unit substrate regions 100 during a process for manufacturing a liquid crystal display is formed between the first voltage supplying wires 136, the second voltage supplying wires 138, the first cell pad 129, and the second cell pad 179. The guard ring 5 surrounds outer portions of the unit substrate regions 100 and is provided between the first voltage supplying wire 136, the second voltage supplying wire 138, the first cell pad 129, and the second cell pad 179. The guard ring 5 is classified as an overlapped area (OA) through which the first connection bridge 272 and the second connection bridge 276 pass and a non-overlapped area (NA) through which the first connection bridge 272 and the second connection bridge 276 do not pass.

That is, the first connection bridge 272 passes over the guard ring 5 of the overlapped area (OA) and connects the first voltage supplying wire 136 and the first and second cell pads 129 and 179, and the second connection bridge 276 passes over the guard ring 5 of the overlapped area (OA) and connects the second voltage supplying wire 138 and the first and second cell pads 129 and 179. The guard ring 5 is formed of the same material as at least one of the first voltage supplying wires 136, the second voltage supplying wires 138, the first cell pad 129, and the second cell pad 179, it is formed on the same layer by the same process, or it can be formed on a different layer by a different process.

Referring to FIG. 3 and FIG. 4, the guard ring 5 is provided between the first voltage supplying wire 136 and the first cell pad 129 on the mother substrate 1, and the first connection bridge 272 for connecting the first voltage supplying wire 136 and the first cell pad 129 is provided on the guard ring 5.

The guard ring 5 is formed of at least one material of the gate line 124, the data line 171, or the pixel electrode 191 formed on the unit substrate regions 100. That is, the guard ring 5 can be formed on the same layer, by the same process, and with a same material 127 as the gate line 121, a same material 177 as the data line 171, and a same material 197 as the pixel electrode 191 formed in the unit substrate regions 100, and differing from this, it can be formed on a different layer by a different process.

A light blocking layer 221 is formed on the overlapped area (OA), i.e., on the guard ring 5 through which the first connection bridge 272 passes. For example, the light blocking layer 221 is formed on the same layer by the same process with the same material as the light blocking member 220 formed in the unit substrate regions 100, and differing from this, it can be formed on a different layer by a different process. In another example, the light blocking layer 221 can be formed of an insulating material for insulating the first connection bridge 272 formed on the guard ring 5 and the light blocking layer 221.

The first connection bridge 272 passes over the guard ring 5 and is connected to the first voltage supplying wire 136 and the first cell pad 129. That is, the first connection bridge 272 is connected to the first voltage supplying wire 136 and the first cell pad 129 through contact holes 181 and 182 formed in the gate insulating layer 140 and the passivation layer 180. The first connection bridge 272 is formed on the same layer by the same process with the same material as the common electrode 270 formed in the unit substrate regions 100, and differing from this, it can be formed on a different layer in a different process.

The voltage received by the first voltage supplying pad 135 from an external device is passed through the first voltage supplying wire 136, the first connection bridge 272, and the first cell pad 129, and is transmitted to the pixel electrode 191 formed in the unit substrate regions 100.

Referring to FIG. 4, a sacrificial layer 223 is formed on the non-overlapped area (NA), i.e., on the guard ring 5 over which the first connection bridge 272 does not pass. The sacrificial layer 223 is formed of the photoresist used to form the microcavity layer 200 formed in the unit substrate regions 100.

In detail, the microcavity layer 200 is formed by forming a sacrificial layer with the photoresist, coating a support member on the upper portion, and removing the sacrificial layer by an ashing process. In this instance, the sacrificial layer 223 is formed by using the photoresist used for forming the microcavity layer 200. That is, the sacrificial layer 223 can be formed on the same layer as the microcavity layer 200 by the same process for forming the microcavity layer 200.

FIG. 5 shows a path for a voltage applied by an external device to be transmitted to a common electrode line 274, which corresponds to FIG. 3 and FIG. 4 except for an added configuration in which the first cell pad 129 is connected to the common electrode line 274. Therefore, like elements will have like reference numerals, and no repeated descriptions will be provided.

Referring to FIG. 5, the guard ring 5 is provided between the second voltage supplying wire 138 and the first cell pad 129 on the mother substrate 1, the second connection bridge 276 for connecting the second voltage supplying wire 138 and the first cell pad 129 is provided on the guard ring 5, and the common electrode line 274 connected to the first cell pad 129 is provided.

The second connection bridge 276 is passed over the guard ring 5 and is connected to the second voltage supplying wire 138 and the first cell pad 129. That is, the second connection bridge 276 is connected to the second voltage supplying wire 138 and the first cell pad 129 through contact holes 186 and 187 formed in the gate insulating layer 140 and the passivation layer 180.

Also, the first cell pad 129 is connected to the common electrode line 274 provided on the passivation layer 180 through a contact hole 188 formed in the gate insulating layer 140 and the passivation layer 180.

The voltage received by the second voltage supplying pad 137 from an external device is transmitted to the common electrode 270 formed in a plurality of unit substrate regions 100 through the second voltage supplying wire 138, the second connection bridge 276, the first cell pad 129, and the common electrode line 274.

As an exemplary embodiment, the second connection bridge 276 is separated from the common electrode line 274, the second connection bridge 276 is connected to the common electrode line 274 through the first cell pad 129, and without being restricted to this, the second connection bridge 276 can be directly connected to the common electrode line 274.

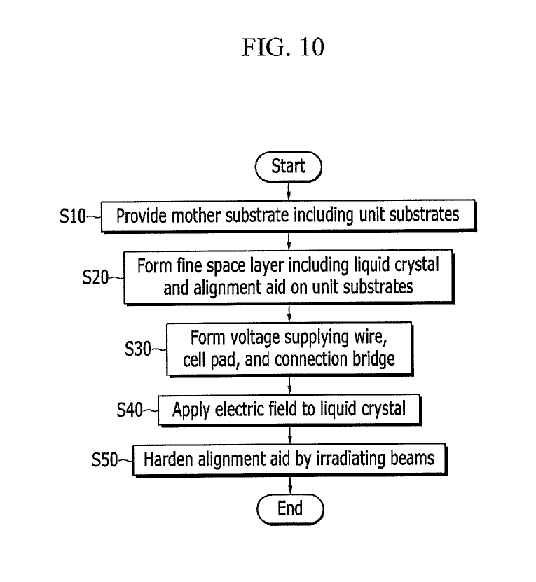

A method for manufacturing a liquid crystal display will now be described with reference to FIG. 10 to FIG. 12.

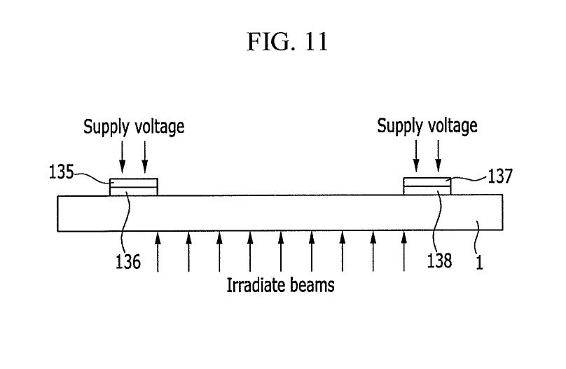

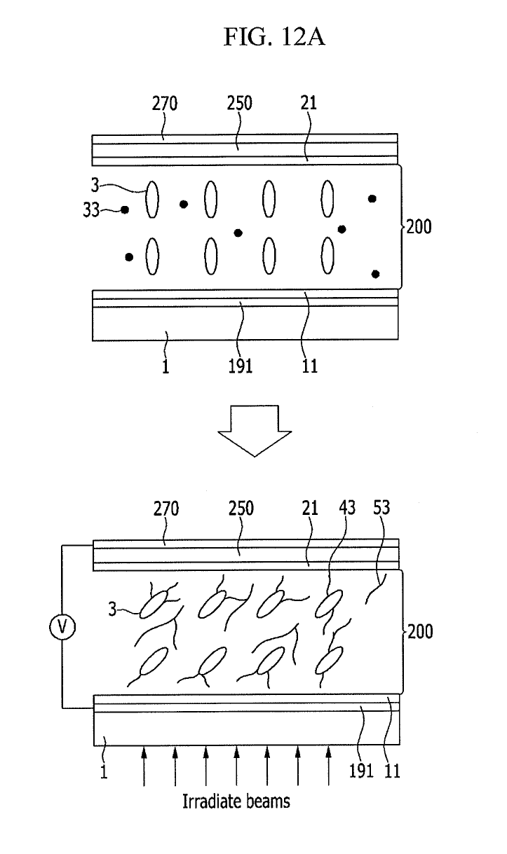

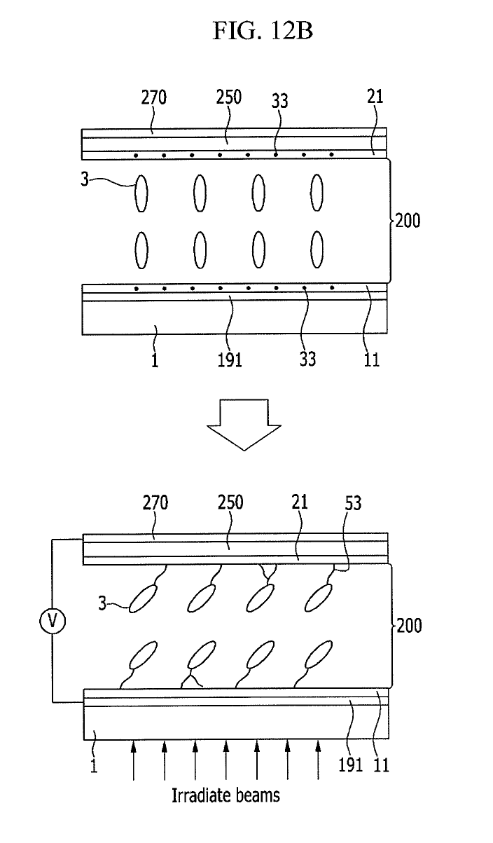

FIG. 10 shows a flowchart of a method for manufacturing a liquid crystal display according to embodiments, FIG. 11 shows a cross-sectional view of the mother substrate 1 of FIG. 1 with respect to a line IX-IX for describing a method for applying an electric field to liquid crystal, and FIG. 12A and FIG. 12B show cross-sectional views of a process for a liquid crystal display to align liquid crystal according to an exemplary embodiment for describing a process for curing an alignment aid by irradiating light beams.

Referring to FIG. 1 to FIG. 10, initial operations S10 to S30 include providing the mother substrate 1 with the plurality of unit substrate regions 100 (operation S10), forming the thin film transistor Q in each of the plurality of unit substrate regions 100, the pixel electrode 191 connected to the thin film transistor Q, the overcoat 250 provided to face the pixel electrode 191, the microcavity layer 200 provided between the pixel electrode 191 and the overcoat 250 and including the liquid crystal 3 and the alignment aid, and the common electrode 270 for covering the microcavity layer 200 (operation S20), and forming the first and second voltage supplying wires 136 and 138, first and second cell pads 129 and 179, and first and second connection bridges 272 and 276 (operation S30) that have been described with reference to FIG. 1 to FIG. 9 and will not be described further.

In subsequent operations S40 and S50, a voltage is supplied to the pixel electrode 191 and the common electrode 270, and the alignment aid is hardened while the electric field is generated.

In detail, referring to FIG. 11, a liquid crystal pre-tilt voltage is supplied to the first voltage supplying pad 135 and the second voltage supplying pad 137 through a voltage supplying probe. The liquid crystal pre-tilt voltages supplied to the first voltage supplying pad 135 and the second voltage supplying pad 137 can be different from each other. For example, the voltage applied to the first voltage supplying pad 135 may be a ground voltage of 0 volts, and the voltage applied to the second voltage supplying pad 137 may be greater than 0 volts, e.g., about 9.5 volts.

In this instance, the liquid crystal pre-tilt voltage supplied to the first voltage supplying pad 135 is transmitted to the pixel electrodes 191 provided in respective ones of the plurality of unit substrate regions 100, and the liquid crystal pre-tilt voltage supplied to the second voltage supplying pad 137 is transmitted to the common electrode 270 provided in the unit substrate regions 100. A voltage difference is generated between the pixel electrode 191 and the common electrode 270 that face each other, and an electric field is generated in the microcavity layer 200 therebetween.

While the electric field is generated in the microcavity layer 200, the alignment aid of the microcavity layer 200 or the alignment aid of the alignment layers 11 and 21 is hardened. When the alignment aid is an ultraviolet ray hardening monomer, beams, e.g., ultraviolet rays, are irradiated to the microcavity layer 200 of the mother substrate 1 so as to harden the alignment aid. In this instance, the beams, e.g., ultraviolet rays, are irradiated from the bottom of the mother substrate 1.

A process for pretilting liquid crystal in the microcavity layer 200 in the process for hardening the alignment aid, i.e., the process for aligning liquid crystal, will be described with reference to FIG. 12A and FIG. 12B together with FIG. 7 to FIG. 10.

FIG. 12A and FIG. 12B show cross-sectional views of a process for aligning liquid crystal of a liquid crystal display according to an exemplary embodiment.

For example, referring to FIG. 12A, the microcavity layer 200 including the liquid crystal 3 and an alignment aid 33 is formed between the mother substrate 1 and the overcoat 250, and a liquid crystal pre-tilt voltage is supplied to the first voltage supplying pad 135 and the second voltage supplying pad 137 to generate an electric field in the microcavity layer 200. The liquid crystal 3 is inclined in response to the electric field. When the beams, e.g., ultraviolet rays, are irradiated to the microcavity layer 200, the alignment aid 33 is hardened while inclined along the liquid crystal 3 to form polymers 43 and 53. The alignment aid 33 that is adjacent to the lower alignment layer 11 and the upper alignment layer 21 is hardened in a direction that is substantially perpendicular to the mother substrate 1, and the alignment aid 33 is hardened while inclined along the liquid crystal 3 while becoming farther from the lower alignment layer 11 and the upper alignment layer 21.

When the electric field is removed from the microcavity layer 200, the liquid crystal 3 maintains the aligned pre-tilted state achieved by the hardened alignment aid, i.e., alignment in accordance with the polymers 43 and 53. When the liquid crystal display is manufactured, the liquid crystal display is driven, and the electric field is generated in the microcavity layer 200, the liquid crystal 3 is inclined in a direction established in accordance with the pre-tilt of the polymers 43 and 53, thereby improving a response speed of the liquid crystal display and reducing afterimages.

In another exemplary embodiment, referring to FIG. 12B, the microcavity layer 200 including the liquid crystal 3 is between the lower alignment layer 11 and the upper alignment layer 21, which include the alignment aid 33. The overcoat 250 is formed, and the liquid crystal pre-tilt voltage is applied to the first voltage supplying pad 135 and the second voltage supplying pad 137 to generate an electric field in the microcavity layer 200. The liquid crystal 3 is inclined in response to the electric field. When the beams, e.g., ultraviolet rays, are irradiated to the microcavity layer 200, the alignment aid 33 of the alignment layers 11 and 21 is hardened while connected to the inclined liquid crystal 3 to form a polymer 53. The polymer 53 is connected to side-chains of the alignment layers 11 and 21. When the electric field is removed from the microcavity layer 200, the liquid crystal 3 maintains the pre-tilted aligned state in accordance with the hardened alignment aid, i.e., in accordance with the polymer 53.

When the process for hardening the alignment aid 33 is finished, the mother substrate assembly is cut by unit substrate regions 100 to complete the liquid crystal panels. A backlight unit including a lamp on a rear of the liquid crystal panel is disposed to complete the liquid crystal display.

According to an exemplary embodiment, when the liquid crystal pre-tilt voltage is supplied to the first voltage supplying pad 135 and the second voltage supplying pad 137 on the mother substrate 1, voltages are transmitted to the pixel electrode 191 and the common electrode 270 of individual unit substrate regions 100 through the plurality of first connection bridges 272 and second connection bridges 276. Therefore, the liquid crystal pre-tilt voltage is supplied to all the unit substrate regions 100 on the mother substrate 1 before cutting the mother substrate 1 into individual units. In other words, the liquid crystal pre-tilt voltage is not supplied to each of the unit substrate regions 100 separately after cutting, but the liquid crystal pre-tilt voltage is supplied to the mother substrate 1, while all the unit substrate regions 100 are still on the mother substrate 1, thereby simplifying the process for aligning the liquid crystal.

By way of summation and review, a technique for forming a microcavity for each pixel and filling liquid crystal in it to realize a display has been developed for the liquid crystal display. The technique forms a sacrificial layer with an organic material, instead of forming an upper plate on a lower plate, forms a supporting member on an upper portion, removes the sacrificial layer, and fills liquid crystal through a liquid crystal injection hole into an empty space formed by removal of the sacrificial layer in order to manufacture the display. However, since the liquid crystal is injected into the microcavity, i.e., the empty space, without an upper substrate, the electric field cannot be generated in all the substrate units included in the mother substrate, thereby requiring application of the electric field to each of the plurality of substrates after cutting the mother substrate into individual unit substrate regions.

In contrast, in exemplary embodiments, the mother substrate including a plurality of unit substrate regions is cut into respective unit substrate regions. However, the liquid crystal pre-tilt voltage is supplied to the mother substrate with the plurality of unit substrate regions before the cutting (rather than supplying the pre-tilt voltage to respective unit substrate regions after cutting), thereby applying the electric field to each of the plurality of substrates before cutting the mother substrate and simplifying the process for aligning the liquid crystal.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A liquid crystal display, comprising:
a mother substrate including a plurality of unit substrate regions;
a first voltage supplying wire and a second voltage supplying wire, each of the first and second voltage supplying wires being between neighboring unit substrate regions;
a first cell pad and a second cell pad on each unit substrate region;
a first connection bridge connecting the first voltage supplying wire, the first cell pad, and the second cell pad; and
a second connection bridge connecting the second voltage supplying wire, the first cell pad, and the second cell pad,
wherein each of the unit substrate regions includes:
a thin film transistor,
a pixel electrode connected to the thin film transistor,
liquid crystal in a microcavity on the pixel electrode,
a common electrode on the liquid crystal, and
an overcoat supporting the microcavity, the overcoat covering the liquid crystal and the common electrode.

2. The liquid crystal display as claimed in claim 1, further comprising:
a lower alignment layer on the pixel electrode; and
an upper alignment layer on the microcavity layer.

3. The liquid crystal display as claimed in claim 1, further comprising a color filter on the common electrode.

4. The liquid crystal display as claimed in claim 1, further comprising:
a first voltage supplying pad on one end of the first voltage supplying wire; and
a second voltage supplying pad on one end of the second voltage supplying wire.

5. The liquid crystal display as claimed in claim 1, wherein the first voltage supplying wire and the second voltage supplying wire include a same material as a gate line or a data line in the unit substrate regions.

6. The liquid crystal display as claimed in claim 1, further comprising a guard ring surrounding each of he unit substrate regions and preventing static electricity from being input to the unit substrate regions, the guard ring being between each of the first voltage supplying wire and the second voltage supplying wire and a corresponding first and second cell pads.

7. The liquid crystal display as claimed in claim 6, wherein the first cell pad is connected to a gate line in the unit substrate regions, and the second cell pad is connected to a data line in the unit substrate regions.

8. The liquid crystal display as claimed in claim 6, wherein the first cell pad and the second cell pad include a same material as a gate line or a data line in the unit substrate regions.

9. The liquid crystal display as claimed in claim 6, wherein the guard ring includes a material of at least one of a gate line, a data line, or a pixel electrode in the unit substrate regions.

10. The liquid crystal display as claimed in claim 6, wherein the guard ring is divided into an overlap area and a non-overlap area, the first connection bridge and the second connection bridge passing through the overlap area, and the first connection bridge and the second connection bridge not passing through the non-overlap area.

11. The liquid crystal display as claimed in claim 10, wherein the overlap area of the guard ring includes a light blocking layer, and the non-overlap area of the guard ring includes a sacrificial layer.

12. The liquid crystal display as claimed in claim 11, wherein the light blocking layer includes a same material as a light blocking member in the unit substrate regions.

13. The liquid crystal display as claimed in claim 11, wherein the sacrificial layer includes a same photoresist as the microcavity layer.

14. The liquid crystal display as claimed in claim 1, wherein the first connection bridge and the second connection bridge include a same material as the common electrode.

15. A method for manufacturing a liquid crystal display, the method comprising:
providing a mother substrate including a plurality of unit substrate regions;
forming a thin film transistor in each of the unit substrate regions, a pixel electrode connected to the thin film transistor, liquid crystal in a microcavity on the pixel electrode, a common electrode on the liquid crystal, and an overcoat for supporting the microcavity and covering the liquid crystal and the common electrode;
forming a first voltage supplying wire and a second voltage supplying wire between neighboring unit substrate regions;
forming a first cell pad and a second cell pad between the first voltage supplying wire, the second voltage supplying wire, and the unit substrate regions, a first connection bridge for connecting the first voltage supplying wire, the first cell pad, and the second cell pad, and a second connection bridge for connecting the second voltage supplying wire, the first cell pad, and the second cell pad;
pre-tilting the liquid crystal by supplying a voltage to the pixel electrode and the common electrode; and
hardening the alignment aid by irradiating beams to the mother substrate.

16. The method as claimed in claim 15, further comprising forming a first voltage supplying pad at one end of the first voltage supplying wire and a second voltage supplying pad at one end of the second voltage supplying wire.

17. The method as claimed in claim 16, wherein the first cell pad is connected to a gate line formed in the unit substrate regions, and the second cell pad is connected to a data line formed in the unit substrate regions.

18. The method as claimed in claim 16, wherein hardening the alignment aid by irradiating beams to the mother substrate includes irradiating ultraviolet rays from a lower portion of the mother substrate.

19. The method as claimed in claim 15, further comprising forming a guard ring for surrounding the unit substrate regions, the guard ring being provided between the first voltage supplying wire, the second voltage supplying wire, the first cell pad, and the second cell pad, and preventing static electricity from being input to the unit substrate regions is further included.

20. The method as claimed in claim 19, wherein the guard ring is formed of a material of at least one of a gate line, a data line, or a pixel electrode formed in the unit substrate regions.
